(19) United States
(12) Patent Application Publication
(10) Pub. No.: US 2026/0354147 A1
(43) Pub. Date: Nov. 5, 2026

(54) SEMICONDUCTOR DEVICES AND METHODS THEREOF WITH SELECTIVELY FORMED ISOLATION LAYERS

(71) Applicant: Taiwan Semiconductor Manufacturing Company, Ltd., Hsinchu (TW)

(72) Inventors: Po-Yu Huang, Hsinchu (TW); Shih-Chieh Wu, Hsinchu (TW); I-Wen Wu, Hsinchu (TW); Chen-Ming Lee, Hsinchu (TW); Mei-Yun Wang, Hsinchu (TW)

(73) Assignee: Taiwan Semiconductor Manufacturing Company, Ltd., Hsinchu (TW)

(21) Appl. No.: 19/743,370

(22) Filed: Jul. 15, 2026

Related U.S. Application Data
(62) Division of application No. 18/393,890, filed on Dec. 22, 2023.
(60) Provisional application No. 63/609,687, filed on Dec. 13, 2023.

(51) Int. Cl. H10W 20/20; H10W 20/00

(52) U.S. Cl. CPC H10W 20/20; H10W 20/023

(57) ABSTRACT

Semiconductor devices and method for forming the same are provided. The semiconductor devices include a substrate having a frontside and a backside, a source/drain structure disposed on the frontside of the substrate, a backside via that includes a trench filled with a conducting material that is exposed at the backside of the substrate, extends through the substrate, and electrically couples with the source/drain structure, and an isolation layer that includes a dielectric material disposed between and separating the substrate and the backside via, wherein the isolation layer selectively covers a first portion of sidewalls of the trench between the substrate and the backside via and does not cover a second portion of the sidewalls of the trench.

### CROSS REFERENCE TO RELATED APPLICATIONS

This application claims the benefit as a division of U.S. Patent Application No. 18/393,890, filed Dec. 22, 2023, which in turn claims the benefit of U.S. Provisional Application No. 63/609,687, filed Dec. 13, 2023. U.S. Patent Application No. 18/393,890 and U.S. Provisional Application No. 63/609,687 are incorporated herein by reference.

### BACKGROUND

The semiconductor integrated circuit (IC) industry has continued its rapid growth in recent years. Technological advancements in IC materials and design have led to continuous improvements in the generations of ICs. With each new generation, the circuits become smaller and more complex than their predecessors, resulting in higher functional density (i.e., the number of interconnected devices per chip area) and smaller geometric sizes (i.e., the smallest component or line that can be created using a fabrication process). This scaling down process has been beneficial in increasing production efficiency and reducing associated costs. However, as feature sizes continue to shrink, the manufacturing process becomes more challenging, and it becomes increasingly difficult to ensure the reliability of semiconductor devices. As a result, the industry faces the ongoing challenge of developing processes that can create smaller, more reliable ICs.

### BRIEF DESCRIPTION OF DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flowchart illustrating an exemplary method for forming a semiconductor device or structure in accordance with some embodiments;

FIGS. 2-8 include cross-sectional views of a portion of a semiconductor device at various stages in an integrated circuit manufacturing process in accordance with some embodiments;

FIG. 9 is an image of a cross-section of a sample fabricated during experimental investigations leading to certain aspects of an embodiment, and a graph representing material measurements of the sample along a scan line; and

FIGS. 10 and 11 include cross-sectional views of a portion of a semiconductor device at various stages in an integrated circuit manufacturing process in accordance with some embodiments.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

As used herein, the terms such as "first," "second" and "third" describe various elements, components, regions, layers and/or sections, but these elements, components, regions, layers and/or sections should not be limited by these terms. These terms may be only used to distinguish one element, component, region, layer or section from another. The terms such as "first," "second" and "third" when used herein do not imply a sequence or order unless clearly indicated by the context.

Furthermore, spatially relative terms, such as “over”, “overlying”, “above”, “upper”, “top”, “under”, “underlying”, “below”, “lower”, “bottom”, and the like, may be used herein for ease of description to describe one element’s or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. When a spatially relative term, such as those listed above, is used to describe a first element with respect to a second element, the first element may be directly on the other element, or intervening elements or layers may be present. When an element or layer is referred to as being “on” another element or layer, it is directly on and in contact with the other element or layer.

It is noted that references in the specification to “one embodiment,” “an embodiment,” “an example embodiment,” “exemplary,” “example,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to affect such feature, structure, or characteristic in connection with other embodiments whether or not explicitly described.

Some embodiments of the disclosure will now be described with reference to the drawings, wherein like reference numerals are generally used to refer to like elements throughout. In the following description, for purposes of explanation, numerous specific details are set forth in order to provide a thorough understanding of the claimed subject matter. It is evident, however, that the claimed subject matter may be practiced without these specific details. In other instances, structures and devices are illustrated in block diagram form in order to facilitate describing the claimed subject matter.

Additional operations can be provided before, during, and/or after the stages described in these embodiments. Some of the stages that are described can be replaced or eliminated for different embodiments. Additional features can be added to the semiconductor device structure. Some of the features described below can be replaced or eliminated for different embodiments. Although some embodiments are discussed with operations performed in a particular order, these operations may be performed in another logical order.

As used herein, a “layer” is a region, such as an area comprising arbitrary boundaries, and does not necessarily comprise a uniform thickness. For example, a layer can be a region comprising at least some variation in thickness.

Methods are disclosed herein for fabricating semiconductor devices having selectively formed isolation layers adjacent to backside vias. For the sake of brevity, conventional techniques related to conventional semiconductor device fabrication may not be described in detail herein. Moreover, the various tasks and processes described herein may be incorporated into a more comprehensive procedure or process having additional functionality not described in detail herein. In particular, various processes in the fabrication of semiconductor devices are well-known and so, in the interest of brevity, many conventional processes will only be mentioned briefly herein or will be omitted entirely without providing the well-known process details. As will be readily apparent to those skilled in the art upon a complete reading of the disclosure, the structures disclosed herein may be employed with a variety of technologies, and may be incorporated into a variety of semiconductor devices and products. Further, it is noted that semiconductor device structures include a varying number of components and that single components shown in the illustrations may be representative of multiple components.

In certain semiconductor device applications, a source power connection is provided on a backside of a semiconductor device to promote reduced overall size and power consumption. In such applications, a source/drain structure disposed on a frontside of the semiconductor device may be electrically coupled to a power rail disposed on a backside of the semiconductor device by a backside via. Preferably, the backside via is configured to provide low resistance, low capacitance, and low leakage current.

Typically, the backside via includes a trench extending through a substrate that is filled with a conductive material that is exposed at the backside of the semiconductor device and electrically couples the source/drain structure and the power rail. To reduce a likelihood of a current leak from the backside via to the substrate, an isolation layer formed of a dielectric material may be deposited within the trench that covers an entirety of sidewalls and a base of the trench prior to filling the trench with the conductive material. However, this may increase resistance of the backside via due to the reduced dimension of the conductive material. Further, additional processing steps are necessary to remove a portion of the isolation layer from a base of the trench and thereby expose the source/drain structure.

In various embodiments disclosed herein, a trench may be formed through a backside of a semiconductor device such that the trench is open to the backside of the semiconductor device. In some embodiments, a first portion of sidewalls of the trench is formed of a first material, a second portion of the sidewalls of the trench is formed of a second material that is different from the first material, and a base of the trench is formed of third material that is different from one or both of the first material and the second material. In various embodiments, a uniform isolation layer is selectively formed over the first portion of the sidewalls of the trench by flowing a fluid into the trench that reacts with the first material of the first portion of the sidewalls of the trench, does not react with the second material of the second portion of the sidewalls of the trench, and may or may not react with the third material of the base of the trench, depending on the particular embodiment. A backside via may be formed in the trench that includes a conducting material that is exposed at the backside of the semiconductor device, extends through the substrate, and electrically couples with a source/drain structure of the semiconductor device.

The semiconductor devices and methods disclosed herein provide the selectively formed isolation layer between the substrate and the backside via as an alternative to deposited isolation layers to promote ease of fabrication, reduce fabrication costs, lower resistance of the backside via, and promote access to the base of the trench for subsequent processing steps.

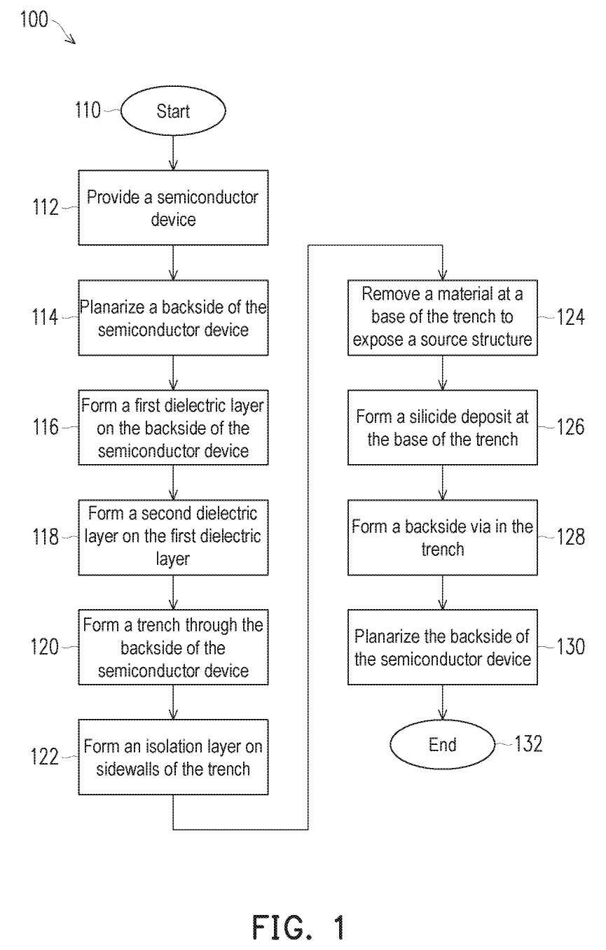

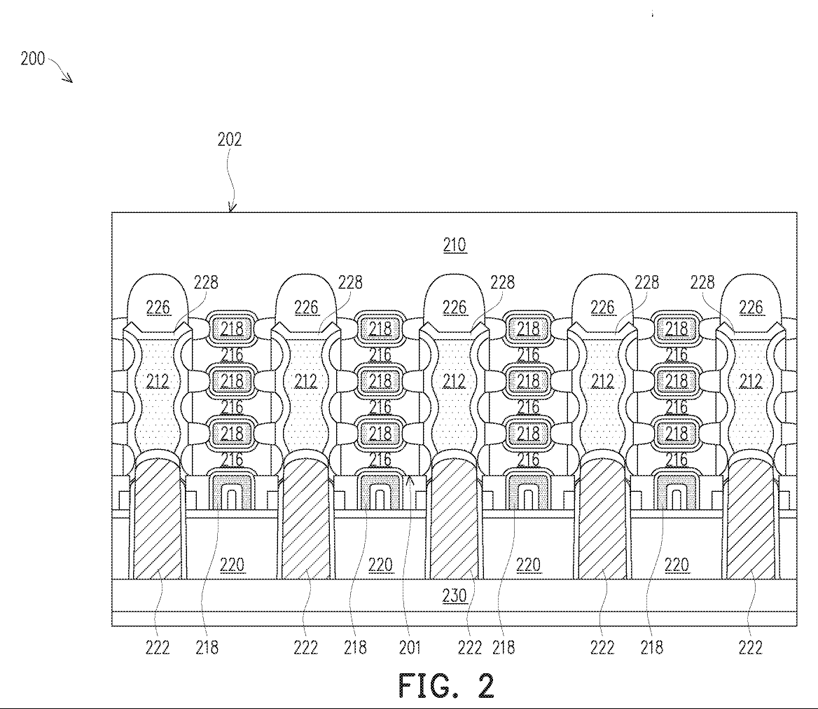

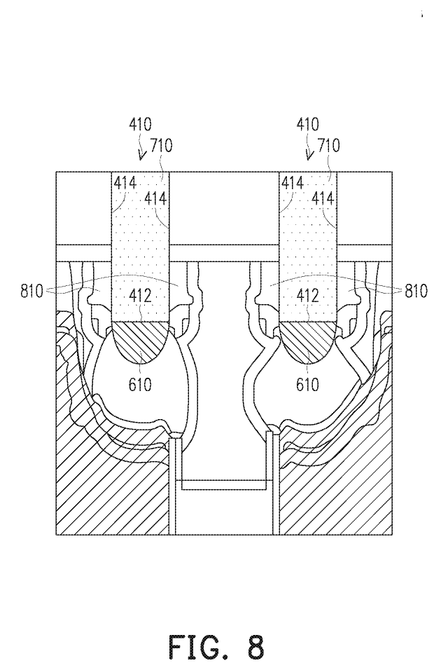

Referring to FIG. 1, an exemplary method 100 is presented for forming a semiconductor device or structure, such as a non-planar transistor device, according to one or more embodiments of the present disclosure. For example, at least some of the operations (or steps) of the method 100 can be used to form a FinFET device, a GAA FET device, a nanosheet transistor device, a nanowire transistor device, a vertical transistor device, or the like. It is noted that the method 100 is merely an example, and is not intended to limit the present disclosure. Accordingly, it is understood that additional operations may be provided before, during, and after the method 100 of FIG. 1, and that some other operations may only be briefly described herein. For convenience, certain operations of the method 100 are described in reference to cross-sectional views of an example gate-all-around (GAA) field-effect-transistor (FET) device 200 (also referred to as the semiconductor device 200) at various fabrication stages of an integrated circuit manufacturing process as shown in FIGS. 2-8. However, it will be understood that the semiconductor devices and the methods disclosed herein are not limited to the method 100 or the examples shown in FIGS. 2-8. The cross-sectional views of FIGS. 2-7 are in a direction perpendicular to the lengthwise direction of an active gate structure 218 of the semiconductor device 200 and the cross-sectional view of FIG. 8 is in a direction parallel to the lengthwise direction of the active gate structure 218 of the semiconductor device 200.

The method 100 may start at 110. At 112, the method 100 may include providing the semiconductor device 200. The semiconductor device 200 may include a substrate 210 having a frontside 201 and a backside 202. The substrate 210 may have electrical circuitry formed in and/or thereupon, for example, to define a transistor structure disposed on the frontside 201 thereof. The transistor structure may include source/drain structures 212 disposed on the frontside 201 of the substrate 210, a plurality of channel layers 216 vertically separated from one another between the source/drain structures 212, and a gate structure 218 located above and around each of the plurality of channel layers 216. In this disclosure, a source and a drain are interchangeably used, and the structures thereof are substantially the same. Various methods are known in the art that may be used to produce the semiconductor device 200 and therefore such processes are not discussed in detail herein.

The components of the semiconductor device 200 may be formed of various materials including those commonly employed in semiconductor integrated circuit fabrication. In some embodiments, the substrate 210 may be a semiconductor substrate, such as a bulk semiconductor, a semiconductor-on-insulator (SOI) substrate, or the like, which may be doped (e.g., with a p-type or an n-type dopant) or undoped. The substrate 210 may be a wafer, such as a silicon wafer. Generally, an SOI substrate includes a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 210 may include silicon; germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GalnAs, GaInP, and/or GaInAsP; or combinations thereof.

In various embodiments, the channel layers 216 may include, for example, a compound semiconductor material such as silicon carbide, gallium arsenide, gallium phosphide, indium phosphide, indium arsenide, and/or indium antimonide, an alloy semiconductor material such as GaAsP, AlInAs, AlGaAs, InGaAs, GaInP, and/or GaInAsP, or combinations thereof. In an embodiment, each of the channel layers 216 is silicon that may be undoped or substantially dopant free (i.e., having an extrinsic dopant concentration from about 0 cm⁻³ to about 1x10¹⁷ cm⁻³), where for example, no intentional doping is performed when forming the channel layers 216 (e.g., of silicon).

In various embodiments, the channel layers 216 may be intentionally doped. For example, when the semiconductor device 200 is configured in n-type (and operates in an enhancement mode), each of the channel layers 216 may be silicon that is doped with a p-type dopant such as boron (B), aluminum (Al), indium (In), and gallium (Ga); and when the semiconductor device 200 is configured in p-type (and operates in an enhancement mode), each of the channel layers 216 may be silicon that is doped with an n-type dopant such as phosphorus (P), arsenic (As), and antimony (Sb). In another example, when the semiconductor device 200 is configured in n-type (and operates in a depletion mode), each of the channel layers 216 may be silicon that is doped with an n-type dopant instead; and when the semiconductor device 200 is configured in p-type (and operates in a depletion mode), each of the channel layers 216 may be silicon that is doped with a p-type dopant. In some embodiments, each of the channel layers 216 may include different compositions among them.

In various embodiments, the channel layers 216 may have the same or different thicknesses from one layer to another layer. The thickness of each of the channel layers 216 may range, for example, from few nanometers to few tens of nanometers. In an embodiment, each of the channel layers 216 has a thickness ranging from about 5 nm to about 20 nm. It should be understood that the semiconductor device 200 can include any number of the channel layers 216 while remaining within the scope of the present disclosure.

Inner spacers may be disposed along respective etched ends of the channel layers 216. The inner spacers can be formed of, for example, silicon nitride, silicoboron carbonitride, silicon carbonitride, silicon carbon oxynitride, or any other type of dielectric material (e.g., a dielectric material having a dielectric constant k of less than about 5) appropriate to the role of forming an insulating gate sidewall spacers of transistors.

In various embodiments, gate spacers can be disposed to enclose portions of the gate structure 218. The gate spacers may include a single conformal layer or a combination of two or more conformal layers. It should be understood that any gate spacer, formed as a combination of any number of conformal layers, can be formed, while remaining within the scope of the present disclosure. In some embodiments, each of the conformal layers may include a dielectric material selected from the group consisting of: silicon nitride, silicon oxynitride, silicon carbonitride, silicon carbide, silicon oxycarbide, the like, or combinations thereof. Each of the conformal layers may have a thickness ranging from about 2 angstroms (Å) to about 500 Å.

In various embodiments, the gate structure 218 includes a gate dielectric and a gate metal. In such embodiments, the gate dielectric and gate metal can each be formed with one or more layers. In some embodiments in which the gate dielectric and the gate metal each include a single layer, the gate dielectric can wrap around each of the channel layers 216, for example, the top and bottom surfaces and certain sidewalls. The gate dielectric may be formed of different high-k dielectric materials or a similar high-k dielectric material. Example high-k dielectric materials include a metal oxide, nitride, or a silicate of Hf, Al, Zr, Ta, La, Mg, Ba, Ti, Pb, and combinations thereof. The gate dielectric may include a stack of multiple high-k dielectric materials.

The gate metal can wrap around each of the channel layers 216 with the gate dielectric disposed therebetween. Specifically, the gate metal can include a number of gate metal sections abutted to each other. Each of the gate metal sections can extend not only along a horizontal plane, but also along a vertical direction. As such, two adjacent ones of the gate metal sections can adjoin together to wrap around a corresponding one of the channel layers 216, with the gate dielectric disposed therebetween.

The gate metal may include a stack of multiple metal materials. For example, the gate metal may be a p-type work function layer, an n-type work function layer, multi-layers thereof, or combinations thereof. The work function layer may also be referred to as a work function metal. Example p-type work function metals that may include TiN, TAN, Ru, Mo, Al, WN, ZrSi₂, MoSi₂, TaSi₂, NiSi₂, WN, other suitable p-type work function materials, or combinations thereof. Example n-type work function metals that may include Ti, Ag, TaAl, TaAIC, TiAIN, TAC, TACN, TaSiN, Mn, Zr, other suitable n–type work function materials, or combinations thereof.

The source/drain structures 212 are electrically coupled to the respective channel layers 216. In various embodiments, the channel layers 216 may collectively function as the conduction channel of a GAA transistor. In-situ doping (ISD) may be applied to form doped source/drain structures 212, thereby creating the junctions for the GAA transistors. N-type and p-type FETs are formed by implanting different types of dopants to selected regions of the device to form the junction(s). N-type devices can be formed by implanting arsenic (As) or phosphorous (P), and p-type devices can be formed by implanting boron (B).

An inter-layer dielectric layer (ILD) 220 may be disposed between the gate structure 218 and the frontside 201 of the semiconductor device 200. The ILD 220 may include or be formed of a dielectric material such as, for example, silicon oxide, phosphosilicate glass (PSG), borosilicate glass (BSG), boron-doped phosphosilicate glass (BPSG), undoped silicate glass (USG), or combinations thereof.

A metal drain (MD) structure 222 may be disposed between the source/drain structure 212 and the frontside 201 of the substrate 210. An LO 226 may be disposed between the source/drain structure 212 and the backside 202 of the substrate 210.

A source/drain isolation layer 228 may be disposed adjacent to and in contact with the source/drain structures 212. The source/drain insolation layer 228 may include or be formed of an insulative material such as, for example, silicon dioxide (SiO₂), silicon nitride (Si₃N₄), a high-k dielectric material (e.g., hafnium oxide (HfO₂) or aluminum oxide (Al₂O₃)), and polysilicon.

The frontside 201 of the substrate 210 may be covered with a third insulation layer 230 formed of or including a third dielectric material. The third insulation layer 230 may include or be formed of various dielectric materials such as silicon nitride (SiN).

At 114, the method 100 may include preparing the substrate 210 of the semiconductor device 200 for depositing additional layers thereon. The substrate 210 may be prepared by, for example, thinning and/or planarizing the backside 202 of the substrate 210, as presented in FIG. 2. In some embodiments, a chemical mechanical polishing (CMP) process may be performed on the backside 202 of the substrate 210. In some embodiments, the substrate 210 may be thinned and/or planarized to have a thickness of about 10 to 50 nanometers from the backside 202 to a portion of the gate structure 218 closest to the backside 202.

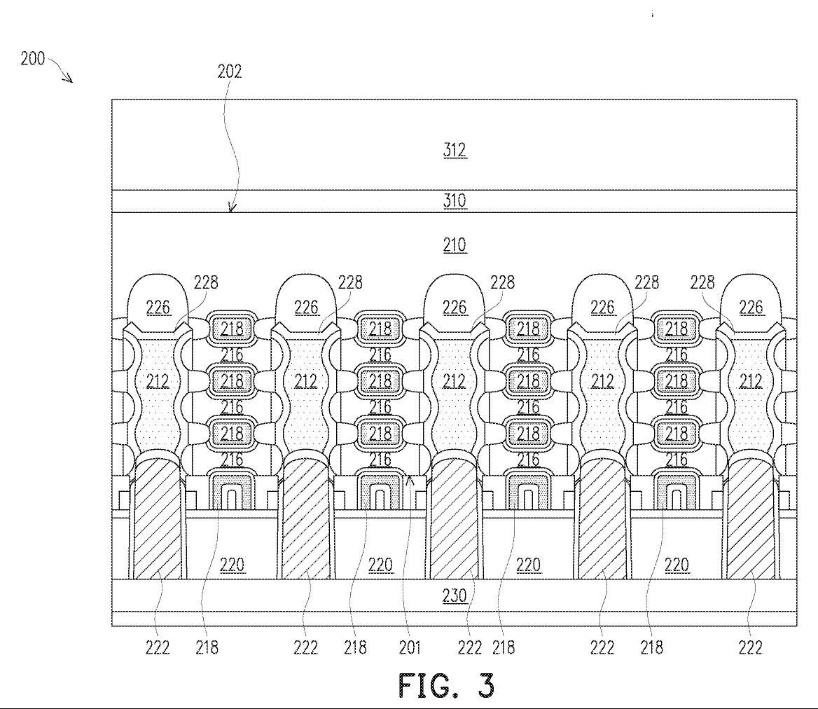

At 116, the method 100 may include forming a first masking layer 310 of a first dielectric material on the backside 202 of the substrate 210 and, at 118, the method 100 may include forming a second masking layer 312 of a second dielectric material on the first masking layer 310, as presented in FIG. 3. The first masking layer 310 and the second masking layer 312 may include or be formed of various dielectric materials. In one embodiment, the first masking layer 310 is formed of silicon nitride (SiN) and the second masking layer 312 is formed of silicon dioxide (SiO₂). In some embodiments, the first masking layer 310 may have a thickness of about 5 to 15 nanometers and the second masking layer 312 may have a thickness of about 15 to 45 nanometers. Various processes may be used to form the first masking layer 310 and the second masking layer 312. In some embodiments, the first masking layer 310 and the second masking layer 312 may each be formed by a film deposition process.

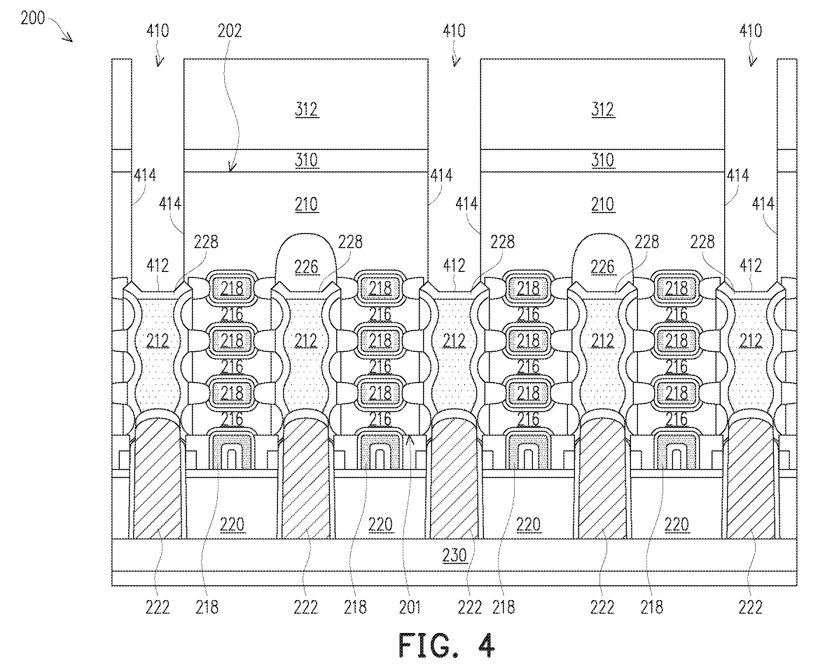

At 120, the method 100 may include forming a trench 410 through the second masking layer 312, the first masking layer 310, and the backside 202 of the substrate 210 such that the trench 410 is open to the backside 202 of the substrate 210, as presented in FIG. 4. Various processes may be used to form the trench 410. In some embodiments, the trench 410 may be formed by one or more photolithography and etching processes. In some embodiments, the trench 410 may have a depth of about 30 to 110 nanometers and a width of about 5 to 30 nanometers. In some embodiments, the trench 410 may gave a ratio of a width thereof to a thickness of the isolation layer in a range of between 6 and 12. In some embodiments, the trench 410 may be formed to a depth sufficient such that a base 412 of the trench 410 is defined by the isolation layer 228, if present, or a portion of the source/drain structure 212.

A first portion of sidewalls 414 of the trench 410 may be formed of first material, a second portion of the sidewalls 414 of the trench 410 may formed of a second material that is different from the first material, and the base 412 of the trench 410 may be formed of third material that is different from the first material and the second material. For example, the sidewalls 414 of the trench 410 may include exposed surfaces of the first masking layer 310, the second masking layer 312, the substrate 210, the isolation layer 228, the source/drain structure 212, a shallow trench isolation layer, and/or various other components of the semiconductor device 200.

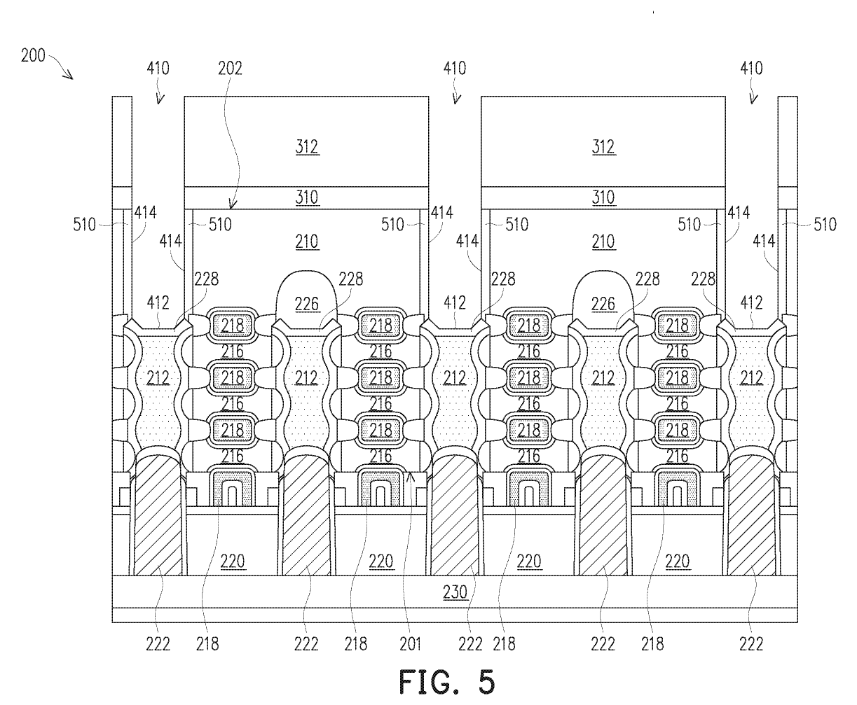

At 122, the method 100 may include forming a uniform isolation layer 510 over the first portion of the sidewalls 414 of the trench 410, as presented in FIG. 5, by flowing a fluid into the trench 410 that reacts with materials that define at least a portion of the sidewalls 414 of the trench 410. Various processes may be used to form the isolation layer 510. In some embodiments, the isolation layer 510 may be formed by a physical vapor deposition (PVD) process. In one embodiment, forming of the isolation layer 510 includes flowing a fluid comprising either nitrogen or oxygen into the trench 410 at a flow rate in a range of 1 to 20 sccm, at a power in a range of 500 to 2000 W, under a pressure in a range of 10 to 100 torr, and for a time in a range of 60 to 360 seconds.

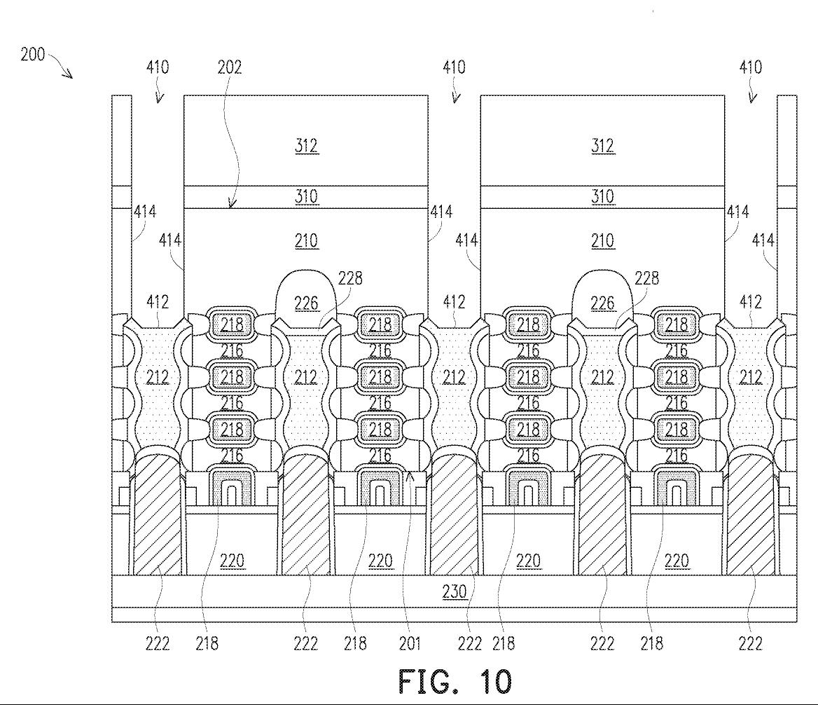

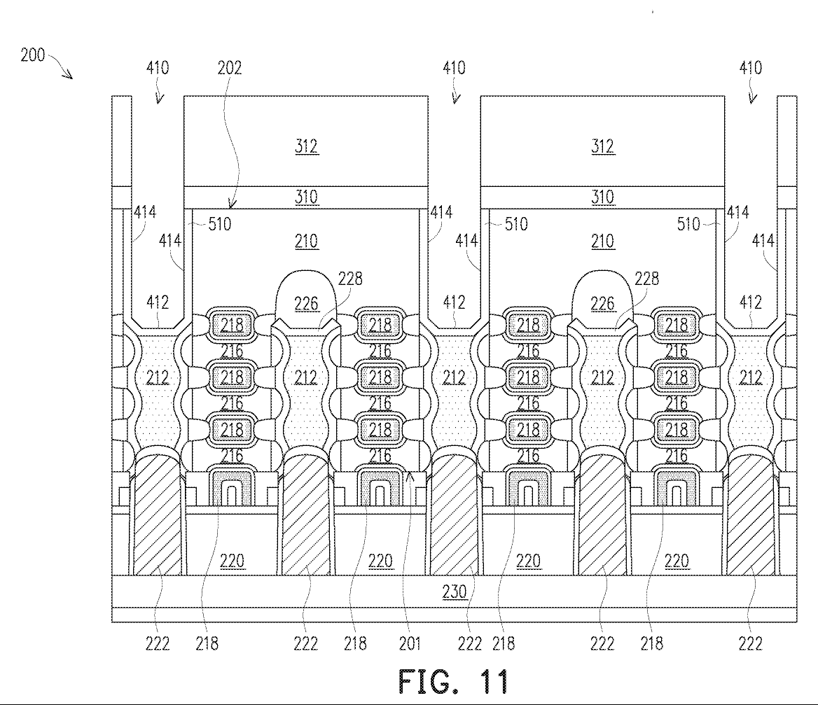

In various embodiments, the fluid reacts with the first material of the first portion of the sidewalls 414 of the trench 410, does not react with the second material of the second portion of the sidewalls 414 of the trench 410 or otherwise does not form the isolation layer 510 thereon, and depending on the embodiment, does or does not react with the third material of the base 412 of the trench 410. For example, FIGS. 4 and 5 present the base 412 of the trench 410 as being defined by the isolation layer 228 and the isolation layer 510 is not formed thereon. In contrast, FIGS. 10 and 11 present the base 412 of the trench 410 as being defined by an exposed portion of the source/drain structure 212 and the isolation layer 510 is formed thereon.

For example, the first portion of the sidewalls 414 may be exposed surfaces of the substrate 210 and the second material and the third material may be exposed surfaces of other components, such as the first masking layer 310, the second masking layer 312, the insolation layer 228, the source/drain structure 212, a shallow trench isolation layer, and/or various other components of the semiconductor device 200. In some embodiments, the third material may be an exposed portion of the source/drain structure 212 and the fluid may react with the exposed surface of the source/drain structure 212 to form a dielectric material. In various embodiments, the fluid may be a gaseous compound configured to react with the first material to form a dielectric material.

In one embodiment, the first material is silicon, and the fluid is gaseous nitrogen (N₂), oxygen (O₂), or a compound comprising either nitrogen or oxygen that is configured to react with the silicon to form a silicon nitride (SiNₓ) or a silicon oxide (SiOₓ). In various embodiments, the reaction between the first material and the fluid consumes a portion of the first material at the exposed surface thereof and therefore the reaction product (e.g., SiNₓ or SiOₓ) has little to no protrusion from the sidewalls 414 of the trench 410. As such, formation of the isolation layer 510 may have little to no effect on the shape and size of the trench 410.

At 124, the method 100 may include removing material at the base 412 of the trench 410 to expose the source/drain structure 212. In some embodiments, the removed material includes a portion of the isolation layer 228 (e.g., FIGS. 4 and 5). In some embodiments, the removed material includes a portion of the isolation layer 510 (e.g., FIGS. 10 and 11). Various processes may be used to remove the material at the base 412 of the trench 410. In one embodiments, the material at the base 412 of the trench 410 is removed by one or more selective etching processes.

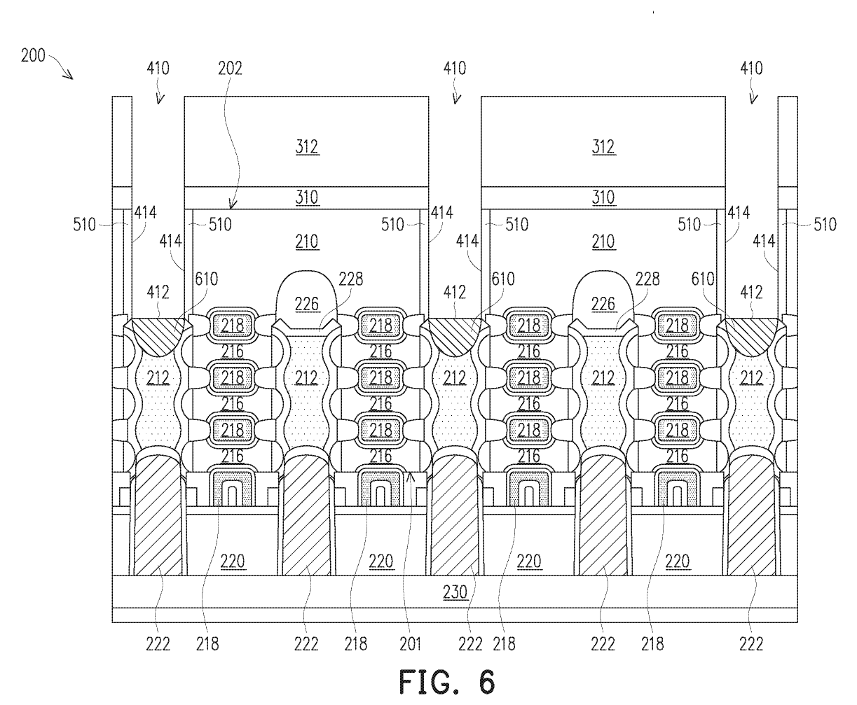

At 126, the method 100 may include forming a conductive deposit 610 disposed at the base 412 of the trench 410 that is electrically coupled with the source/drain structure 212, as presented in FIG. 6. The conductive deposit 610 is configured to promote an electrical connection with the source/drain structure 212. The conductive deposit 610 may be formed of or include various silicide materials, such as titanium silicides (TiSiₓ), nickel silicides (NiSiₓ), cobalt silicides (CoSiₓ), etc. Forming the conductive deposit 610 may be performed by various deposition processes. The conductive deposit 610 may have a thickness in a range of 5 to 10 nanometers.

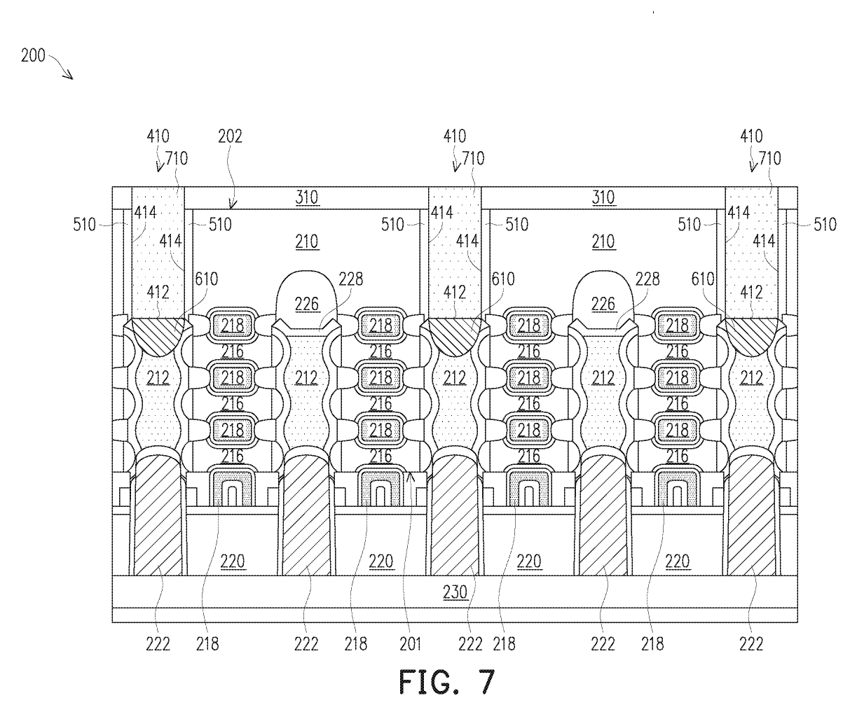

At 128, the method 100 may include forming a backside via 710 in the trench 410, as presented in FIG. 7. The backside via 710 may be formed by various processes. The backside via 710 may include a conducting material that is exposed at the backside 202 of the semiconductor device 200, extends through the substrate 210, and electrically couples with the source/drain structure 212 of the semiconductor device 200. The backside via 710 is configured to provide an electrical connection between the source/drain structure 212 and a power rail on the backside 202 of the semiconductor device 200. The conducting material of the backside via 710 may be formed of or include various conductive materials. Nonlimiting examples include various metallic materials such as titanium-titanium nitride-tungsten alloys, tungsten, cobalt, ruthenium, molybdenum, etc.

At 130, the method 100 may include removing the second masking layer 312 and any other excess materials (e.g., portions of the backside via 710) , as presented in FIG. 7. Various processes may be used to remove the second masking layer 312. In one embodiment, the second masking layer 312 is removed by a chemical mechanical polishing process. Various parameters of the chemical mechanical polishing process may be chosen by one skilled in the art. In some embodiments, an entirety of the second masking layer 312 located adjacent to the first masking layer 310 is removed. In some embodiments, an entirety of the first masking layer 310 is removed.

The method 100 may end at 132. FIGS. 7 and 8 present cross-sectional views of the semiconductor device 200 upon completion of the method 100 in accordance with various embodiments, with the cross-section of FIG. 8 being perpendicular to the cross-sectional view of FIG. 7. As represented, the isolation layer 510 is limited to covering only certain portions of the sidewalls 414 of the trench 410. For example, in FIG. 7 the isolation layer 510 defines the portions of the sidewalls 414 originally defined by the exposed surfaces of the substrate 210 but does not define other portions defined by the first masking layer 310. In FIG. 8, portions of the sidewalls 414 are defined, in part, by shallow trench isolations (STIs) 810. As such, the isolation layer 510 is not observable from the view presented in FIG. 8. In addition to only defining select portions of the sidewalls 414, the isolation layer 510 has little to no protrusion into the cavity of the trench 410. As such, the presence of the isolation layer 510 has little to no impact on the dimensions of the trench 410, and therefore the dimensions and performance of the backside via 710.

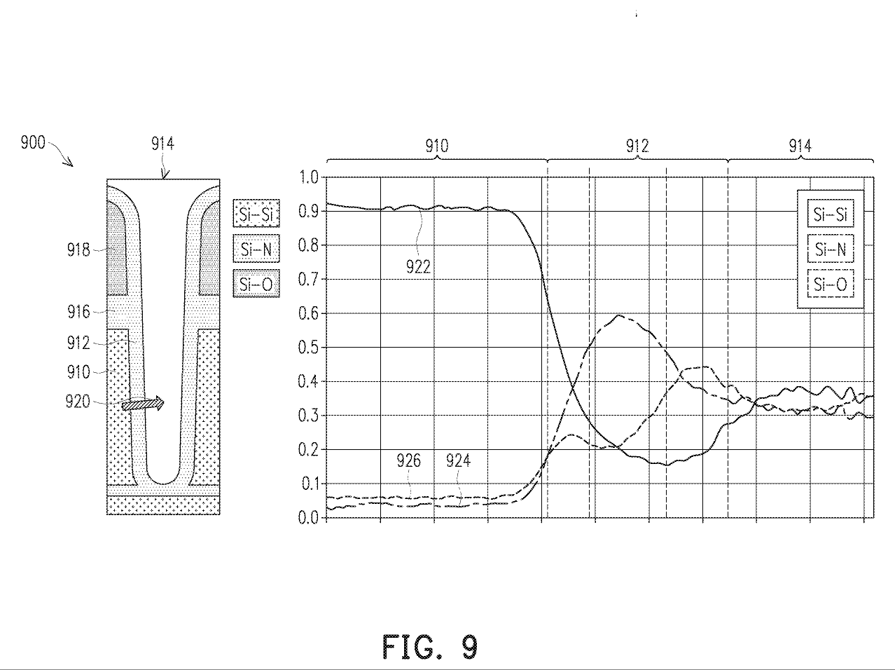

FIG. 9 presents an image of a cross-sectional sample semiconductor device 900 that includes an empty trench 914 formed therein to extend through a substrate 910, a first masking layer 916, and a second masking layer 918. An isolation layer 912 was formed from the substrate 910 by a process similar to steps 112-122 of the method 100 to provide an electrical barrier along sidewalls of the trench 914. The substrate 910 was formed of silicon, the first masking layer 916 was formed of silicon nitride, and the second masking layer 918 was formed of silicon oxide. The isolation layer 912 was formed by a reaction with the substrate 910 to define a portion of the sidewalls of the trench 914 and was formed of silicon nitride.

A plot is provided that presents the presence of certain compounds, that is, silicon, silicon nitride, and silicon oxide, along a scanned line (indicated with an arrow 920) traversing portions of the substrate 910 and the isolation layer 912. The plot indicates relative material content (y-axis) to position (x-axis). More specifically, the plot includes a first line 922 representing relative silicon content, a second line 924 representing relative silicon nitride content, and a third line 926 representing relative silicon oxide content. As the position transitions from the substrate 910, to the isolation layer 912, and into the trench 914, the relative content changes from primarily silicon (e.g., the first line 922 is about 0.91) to a significant decrease in silicon and increases in silicon nitride and then silicon oxide.

The present disclosure therefore provides methods for forming a semiconductor device or structure that may significantly improve resistance properties of a backside via. In some embodiments, the backside via includes an isolation layer selectively formed on portions of sidewalls of the backside via defined by exposed portions of a substrate of the semiconductor device.

In accordance with an embodiment, a semiconductor device is provided that includes a substrate having a frontside and a backside, a source/drain structure disposed on the frontside of the substrate, a backside via that includes a trench filled with a conducting material that is exposed at the backside of the substrate, extends through the substrate, and electrically couples with the source/drain structure, and an isolation layer that includes a dielectric material disposed between and separating the substrate and the backside via, wherein the isolation layer selectively covers a first portion of sidewalls of the trench between the substrate and the backside via and does not cover a second portion of the sidewalls of the trench.

In accordance with another embodiment, a method is provided for forming a semiconductor device. The method includes forming a trench through a backside of a substrate of the semiconductor device with a trench opening on the backside of the substrate, wherein a first portion of sidewalls of the trench is formed of first material, a second portion of the sidewalls of the trench is formed of a second material that is different from the first material, and a base of the trench is formed of third material that is different from the first material and the second material, forming a uniform isolation layer over the first portion of the sidewalls of the trench by flowing a fluid into the trench that forms the isolation layer on the first portion of the sidewalls of the trench, does not form the isolation layer on the second portion or the third portion of the sidewalls of the trench, and forming a backside via in the trench that includes a conducting material that is exposed at the backside of the substrate, extends through the substrate, and electrically couples with a source/drain structure of the semiconductor device.

In accordance with yet another embodiment, a method is provided for forming a semiconductor device. The method includes forming a trench through a backside of a substrate of the semiconductor device with a trench opening at the backside of the substrate, wherein a first portion of sidewalls of the trench is formed of first material, at least a second portion of the sidewalls of the trench is formed of a second material that is different from the first material, and a base of the trench is formed of third material that is different from the first material and the second material, flowing a fluid into the trench that forms a uniform isolation layer on the first portion of the sidewalls of the trench and on the third portion of the base of the trench, and does not form the isolation layer on the second portion of the sidewalls of the trench, removing a portion of the isolation layer covering the base of the trench to expose a portion of a source/drain structure, and forming a backside via in the trench that includes a conducting material that is exposed at the backside of the substrate, extends through the substrate, and electrically couples with the source/drain structure of the semiconductor device.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a substrate having a frontside and a backside;
a source/drain structure disposed on the frontside of the substrate;
a backside via in a trench filled with a conducting material that is exposed at the backside of the substrate, extends through the substrate, and electrically couples with the source/drain structure; and
an isolation layer that includes a dielectric material disposed between and separating the substrate and the backside via, wherein the isolation layer selectively covers a first portion of sidewalls of the trench between the substrate and the backside via and does not cover a second portion of the sidewalls of the trench.

2. The semiconductor device of claim 1, further comprising at least one additional layer formed on the backside of the substrate, wherein the backside via extends through the substrate and the at least one additional layer.

3. The semiconductor device of claim 1, wherein the substrate is formed of silicon and the isolation layer is formed of an oxide of silicon (SiOx) or a nitride of silicon (SiNx).

4. The semiconductor device of claim 1, wherein the isolation layer has a thickness in a range of between 2 and 4 nanometers.

5. The semiconductor device of claim 1, wherein the trench has a width in a range of between 5 and 30 nanometers.

6. The semiconductor device of claim 1, wherein a ratio of a width of the trench to a thickness of the isolation layer is in a range between 6 and 12.

7. The semiconductor device of claim 1, wherein the second portion of the sidewalls of the trench is defined by exposed portions of a shallow trench isolation (STI).

8. The semiconductor device of claim 1, further comprising a second source/drain structure disposed on the frontside of the substrate, a plurality of semiconductor layers vertically separated from one another, and a gate structure that is disposed on and wraps around each of the plurality of semiconductor layers, wherein portions of the gate structure disposed between each of the plurality of semiconductor layers contact the source/drain structure and the second source/drain structure.

9. A semiconductor device, comprising:
a substrate having a frontside and a backside;
a source/drain structure disposed on the frontside of the substrate;
an opening in the substrate that extends from a backside surface of the substrate to the source/drain structure;
a first portion of sidewalls of the opening comprising an isolation layer of a dielectric material; and
a via disposed in the opening and separated from the substrate by the isolation layer.

10. The semiconductor device of claim 9, wherein the substrate comprises silicon and the isolation layer comprises a dielectric material that includes an oxide of silicon (SiOx) or a nitride of silicon (SiNx).

11. The semiconductor device of claim 9, wherein the isolation layer has a thickness in a range of between 2 and 4 nanometers.

12. The semiconductor device of claim 9, wherein the opening has a width in a range of between 5 and 30 nanometers.

13. The semiconductor device of claim 9, further comprising at least one additional layer formed on the backside of the substrate, wherein the via extends through the substrate and the at least one additional layer.

14. The semiconductor device of claim 9, wherein a ratio of a width of the opening to a thickness of the isolation layer is in a range between 6 and 12.

15. The semiconductor device of claim 9, further comprising a second portion of the sidewalls of the opening defined by a shallow trench isolation (STI) feature.

16. The semiconductor device of claim 9, further comprising a second source/drain structure disposed on the frontside of the substrate, a plurality of semiconductor layers vertically separated from one another, and a gate structure that is disposed on and wraps around each of the plurality of semiconductor layers, wherein portions of the gate structure disposed between each of the plurality of semiconductor layers contact the source/drain structure and the second source/drain structure.

17. A semiconductor device, comprising:
a substrate having a frontside and a backside;
a plurality of semiconductor layers vertically separated from one another;
a gate structure that wraps around each of the plurality of semiconductor layers;
a first source/drain structure disposed on a first side of the gate structure on the frontside of the substrate;
a second source/drain structure disposed on a second side of the gate structure on the frontside of the substrate;
an opening in the substrate that extends from a backside surface of the substrate to the first source/drain structure;
a first portion of sidewalls of the opening comprising an isolation layer formed from a dielectric material; and
a via disposed in the opening and separated from the substrate by the isolation layer.

18. The semiconductor device of claim 17, further comprising at least one additional layer formed on the backside of the substrate, wherein the via extends through the substrate and the at least one additional layer.

19. The semiconductor device of claim 17, wherein a ratio of a width of the opening to a thickness of the isolation layer is in a range between 6 and 12.

20. The semiconductor device of claim 17, further comprising a second portion of the sidewalls of the opening defined by a shallow trench isolation (STI) feature.
